(19) United States
(12) Patent Application Publication
(10) Pub. No.: US 2023/0051755 A1
(43) Pub. Date: Feb. 16, 2023

(54) ACOUSTIC TRANSDUCER, METHOD AND SYSTEM

(71) Applicants: Aaron Avagliano, Tomball, TX (US); Navin Sakthivel, Spring, TX (US); Brian Wieneke, Spring, TX (US)

(72) Inventors: Aaron Avagliano, Tomball, TX (US); Navin Sakthivel, Spring, TX (US); Brian Wieneke, Spring, TX (US)

(73) Assignee: Baker Hughes Oilfield Operations LLC, Houston, TX (US)

(21) Appl. No.: 17/401,697

(22) Filed: Aug. 13, 2021

(51) Int. Cl. E21B 28/00; H01L 41/113; H01L 41/314

(52) U.S. Cl. CPC E21B 28/00; H01L 41/113; H01L 41/314

(57) ABSTRACT

An acoustic generator including a piezoelectric crystal, an impedance matching layer directly bonded to the crystal with Van der Waals forces.

### BACKGROUND

Acoustic transducers are employed in many industries and often use impedance matching layers to improve efficient acoustic conduction to another device or portion of a device. Such layers are generally carefully constructed and then adhesively bound to an acoustic generator such as a piezo crystal. While the arts have been fitted from the utility of transducers with impedance matching layers adhered thereto, even greater efficiency in signal conduction with reduced attenuation and scatter would be desired and has eluded the arts.

### SUMMARY

An embodiment of an acoustic generator including a piezoelectric crystal, an impedance matching layer directly bonded to the crystal with Van der Waals forces.

### BRIEF DESCRIPTION OF THE DRAWINGS

The following descriptions should not be considered limiting in any way. With reference to the accompanying drawings, like elements are numbered alike:

FIG. 1 is a schematic perspective view of an acoustic generator as disclosed herein;

FIG. 2 is a schematic view of a Stereolithography (SLA) device as disclosed herein;

FIG. 3 is an enlarged view of a build plate illustrated in FIG. 1; and

FIG. 4 is a view of a wellbore system including the acoustic generator disclosed herein

### DETAILED DESCRIPTION

A detailed description of one or more embodiments of the disclosed apparatus and method are presented herein by way of exemplification and not limitation with reference to the Figures.

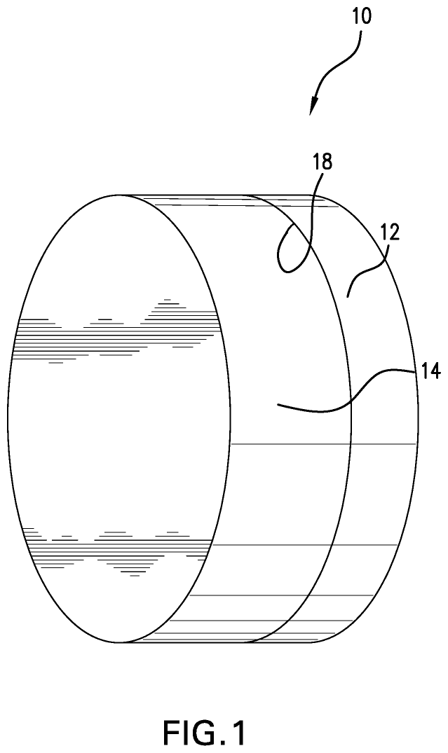

Referring to FIG. 1, an acoustic generator 10 is illustrated having a piezo crystal 12 and an impedance matching layer 14. The impedance matching layer is in intimate contact with a surface 18 of the crystal 12 and without any intermediate adhesive material since the matching layer 14 is directly deposited on the surface 18 in an additive manufacturing process (such as SLA, direct ink writing, etc.). The directly deposited matching layer 14 features chemical bonds that includes Van der Waals forces and a mechanical bond. The Van der Waals forces that bind the layer 14 to the crystal 12 include dipole bonds, hydrogen bonds and dispersion bonds. Each of these types of bonds provide great adhesion of the layer to the crystal and create extremely small to no reflections of acoustic energy passing from the crystal 12 into the layer 14. Further, the mechanical forces strengthen the connection of the impedance matching layer 14 and are due to the deposition of the layer 14 material directly on the surface 18 of the crystal 12. The surface 18 of crystal 12 exhibits a smoothness of less than about 150 micro inches. The layer 14 material initially is a liquid, and in an embodiment a polymer, whose viscosity is less than About 5000 centipoises. The interaction of the liquid and the crystal due to the properties of each results in penetration by the liquid of the surface of the crystal 12. The material comprising layer 14 will stay in the penetrated positions within the crystal 12 when cured and accordingly forms a significant mechanical bond between itself and the crystal 12. The penetration into the crystal 12 also benefits the acoustic generator 10 since the mechanical bond also avoids reflection and scattering of the acoustic signal propagating from the crystal 12 to the impedance matching layer 14.

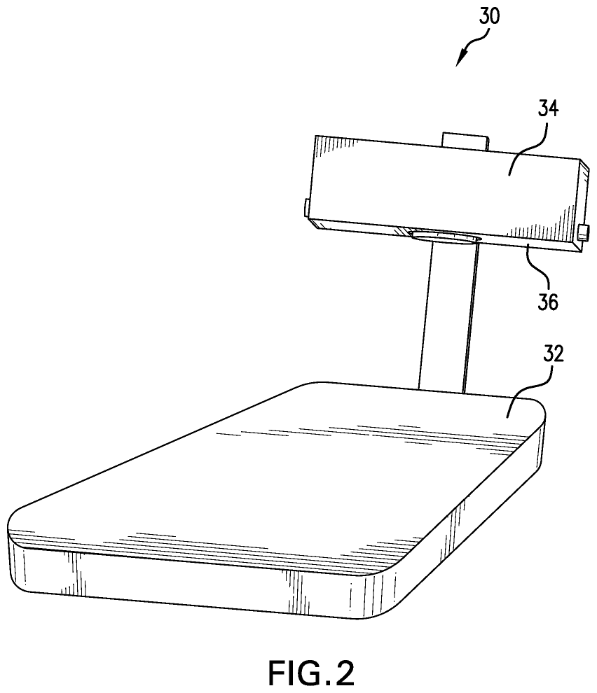

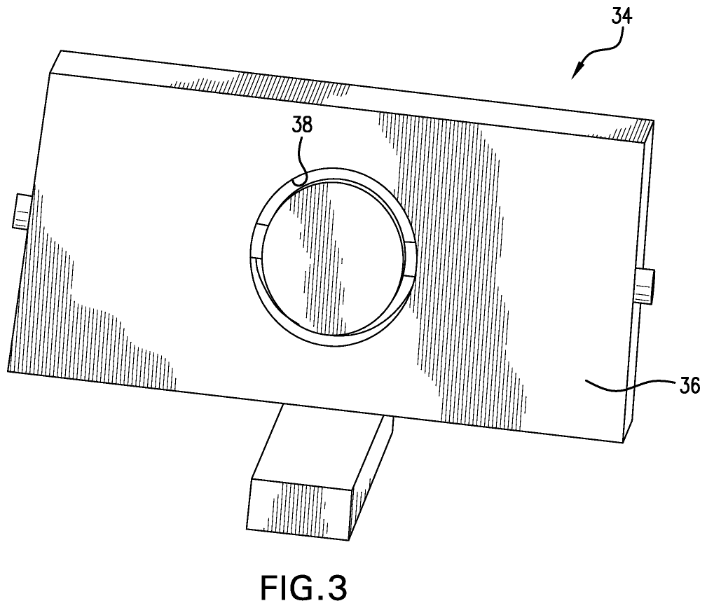

Referring to FIGS. 2 and 3, the acoustic generator as described above can be created using a modified additive manufacturing process. Specifically, in one embodiment, an SLA process and machine 30 are used. The machine 30 comprises a vat 32 and a movable build plate 34. The plate 34 moves as is common in an SLA machine 30, to dip a build surface 36 into the vat (or dip a leading surface of the building part not shown into the vat) followed by light curing (UV light in embodiments) of the feed material from the vat 32 into the prescribed shape. The machine 30 differs from prior art machines in that the plate 34 is modified to allow for reception and support of the crystal 12 of the acoustic generator 10 described herein.

As will be appreciated, SLA machines build onto the build plate. In order to arrive at the generator described above, it was found by the present inventors that there is advantage in causing the surface 18 of the crystal 12 to be coplanar (or as close as possible to coplanar, i.e. within 10%) to enhance the direct bonding of the impedance matching layer 14 to the surface 18 of the crystal 12. Turning to FIG. 3, the plate 34 is enlarged to provide a greater understanding. A recess 38 is made in the build surface 36, the recess 38 exhibiting a depth that allows the surface 18 of crystal 12 to be coplanar (or close to coplanar) with the build surface 36 of the build plate 34. As such, the surface 18 of crystal 12 is subject to the build material directly as would be the build surface 36 in a prior art machine. This supports direct bonding of the build material to the surface 18 providing the benefits noted above.

To secure the crystal 12 in the recess 38, there may be a set screw, a temporary adhesive, a threaded connection, a vacuum connection, etc. Each of these is easily releasable once the additive manufacturing operation is completed and the matching layer 14 is fully formed upon the surface 18 of crystal 12.

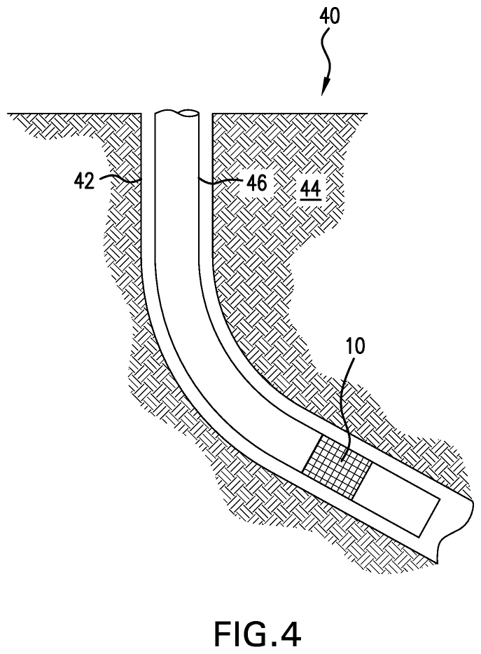

Referring to FIG. 4, a wellbore system 40 is illustrated. System 40 includes a borehole 42 in a subsurface formation 44. A string 46 is disposed in the borehole 42. An acoustic generator 10 is disposed within or as a part of the string 46.

Set forth below are some embodiments of the foregoing disclosure:

Embodiment 1: An acoustic generator including a piezoelectric crystal, an impedance matching layer directly bonded to the crystal with Van der Waals forces.

Embodiment 2: The generator as in any prior embodiment wherein the Van der Waals forces include one or more of dipole bonds, hydrogen bonds, and dispersion bonds.

Embodiment 3: The generator as in any prior embodiment wherein the crystal is cylindrical in shape.

Embodiment 4: The generator as in any prior embodiment wherein crystal includes a surface smoothness less than about 150 micro inches.

Embodiment 5: The generator as in any prior embodiment wherein the impedance layer penetrates the crystal.

Embodiment 6: The generator as in any prior embodiment wherein penetration of the impedance layer upon curing causes a mechanical bond with the crystal.

Embodiment 7: The generator as in any prior embodiment wherein the impedance matching layer is initially formed from a liquid polymer that is cured to the crystal.

Embodiment 8: The generator as in any prior embodiment wherein the liquid polymer has a viscosity of less than about 5000 centipoises.

Embodiment 9: The generator as in any prior embodiment absent any material between the crystal and the impedance matching layer.

Embodiment 10: A method of forming the acoustic generator as in any prior embodiment including disposing the crystal into a recess of a build plate in an additive manufacture machine, depositing material from a vat of the additive manufacturing machine on the crystal, and curing the material on the crystal.

Embodiment 11: The method as in any prior embodiment wherein the curing is by applying light to the material.

Embodiment 12: The method as in any prior embodiment wherein the depositing material from the vat includes penetrating the crystal with the material.

Embodiment 13: The method as in any prior embodiment wherein the curing is by application of UV light.

Embodiment 14: A wellbore system including a borehole in a subsurface formation, a string in the borehole, an acoustic generator as in any prior embodiment disposed within or as a part of the string.

The use of the terms “a” and “an” and “the” and similar referents in the context of describing the invention (especially in the context of the following claims) are to be construed to cover both the singular and the plural, unless otherwise indicated herein or clearly contradicted by context. Further, it should be noted that the terms “first,” “second,” and the like herein do not denote any order, quantity, or importance, but rather are used to distinguish one element from another. The terms “about”, “substantially” and “generally” are intended to include the degree of error associated with measurement of the particular quantity based upon the equipment available at the time of filing the application. For example, “about” and/or “substantially” and/or “generally” can include a range of ±8% or 5%, or 2% of a given value.

The teachings of the present disclosure may be used in a variety of well operations. These operations may involve using one or more treatment agents to treat a formation, the fluids resident in a formation, a wellbore, and/or equipment in the wellbore, such as production tubing. The treatment agents may be in the form of liquids, gases, solids, semi-solids, and mixtures thereof. Illustrative treatment agents include, but are not limited to, fracturing fluids, acids, steam, water, brine, anti-corrosion agents, cement, permeability modifiers, drilling muds, emulsifiers, demulsifiers, tracers, flow improvers etc. Illustrative well operations include, but are not limited to, hydraulic fracturing, stimulation, tracer injection, cleaning, acidizing, steam injection, water flooding, cementing, etc.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited.

What is claimed is:

1. An acoustic generator comprising:
a piezoelectric crystal;
an impedance matching layer directly bonded to the crystal with Van der Waals forces.

2. The generator as claimed in claim 1 wherein the Van der Waals forces include one or more of dipole bonds, hydrogen bonds, and dispersion bonds.

3. The generator as claimed in claim 1 wherein the crystal is cylindrical in shape.

4. The generator as claimed in claim 1 wherein crystal includes a surface smoothness less than about 150 micro inches.

5. The generator as claimed in claim 1 wherein the impedance layer penetrates the crystal.

6. The generator as claimed in claim 5 wherein penetration of the impedance layer upon curing causes a mechanical bond with the crystal.

7. The generator as claimed in claim 1 wherein the impedance matching layer is initially formed from a liquid polymer that is cured to the crystal.

8. The generator as claimed in claim 7 wherein the liquid polymer has a viscosity of less than about 5000 centipoises.

9. The generator as claimed in claim 1 absent any material between the crystal and the impedance matching layer.

10. A method of forming the acoustic generator as claimed in claim 1 comprising:
disposing the crystal into a recess of a build plate in an additive manufacture machine;
depositing material from a vat of the additive manufacturing machine on the crystal; and
curing the material on the crystal.

11. The method as claimed in claim 10 wherein the curing is by applying light to the material.

12. The method as claimed in claim 10 wherein the depositing material from the vat includes penetrating the crystal with the material.

13. The method as claimed in claim 10 wherein the curing is by application of UV light.

14. A wellbore system comprising:
a borehole in a subsurface formation;
a string in the borehole;
an acoustic generator as claimed in claim 1 disposed within or as a part of the string.
